(19) United States
(12) Patent Application Publication
(10) Pub. No.: US 2010/0231244 A1
(43) Pub. Date: Sep. 16, 2010

(54) Method and apparatus for measuring the percentage of fat trim and the percentage of saleable yield on cattle and the like and on their carcasses

(76) Inventors: Neal S. Latman, Amarillo, TX (US); Joseph E. Batson, JR., Amarillo, TX (US); Alan Nicholson, Canyon, TX (US); Ladislado Garza, Amarillo, TX (US); Mike Floyd, Amarillo, TX (US)

Correspondence Address: Harold H. Flanders, 904 Sweetwater Cove, Round Rock, TX, 78681, US

(21) Appl. No.: 12/381,335

(22) Filed: Mar. 11, 2009

(51) Int. Cl. G01R 27/08; G01N 27/04

(52) U.S. Cl. 324/693

(57) ABSTRACT

A method and apparatus for measuring the percentage of fat trim and of saleable yield of cattle and their carcasses including providing power to a transmitting circuit to transmit a signal to electrodes resulting in a potential difference across the electrodes causing a flow of current between the electrodes reflecting the impedance encountered and sending a signal reflecting such information to receiving circuits which pass that data to processing circuits which process that data with other external inputs to produce an output display reflecting an indication of the state of hydration of the animal, comprising:
means for providing a voltage difference across two or more penetrating electrodes; means for maintaining said electrodes in a fixed spatial relation and in good electrical contact with the tissue on which said measurements are to be made; means for measuring the impedance in the region of or between the electrodes; means for transmitting the measured data to processing circuits which process that data with other external inputs to produce an output display reflecting an indication of the state of hydration of the animal, wherein the other external inputs include one or more of the factors for sex, electrode gap, and left side weight; and the output display provides indications of one or more of the outputs produced by formulations of the data reflecting the percentage of fat trim and/or saleable yield and the analyzing monitoring unit may be selected from the group of embodiments consisting of software in a computer, hard wired circuits, printed circuits, integrated circuits, microcircuits, microchips, silicon chips, digital chips, analog chips, hybrid chips and combinations of any or all of the members of this group.

### RIGHTS TO INVENTION UNDER FEDERAL SPONSORED RESEARCH OR DEVELOPMENT

None

### CROSS REFERENCE TO RELATED APPLICATIONS

The following applications co-owned by the same inventive entity were filed of even date herewith: CCC 0805 EQ, 0806 B, and 0807 EQ.

### REFERENCE TO MICROFICHE APPENDIX

None

### BACKGROUND OF THE INVENTION

1. Field of the Invention

The present invention relates generally to a process, apparatus and systems for measuring the state of hydration of an animal and more particularly to a new and improved method and apparatus for use in connection with the measurement of the percentage of fat trim and of saleable yield on cattle and the like and on their carcasses using Bioelectrical Impedance Analysis (BIA), and for such other structure, apparatus, processes, systems, and methods as may be herein disclosed.

The present invention is and may be used in connection with measurements requiring the use of electrodes as described herein and in general. The present invention may be referred to as the “Bovine Carcass Analyzer”

As a specific example, reference is made to Bioelectrical Impedance Analysis (BIA). The initials or acronym BIA may refer to one or more of several slightly different terms all of which may be considered to be equivalent as discussed below and used herein. The meaning is almost always clear from the context of use and for the purposes of this application these terms may in general be used interchangeably. The term Bioelectrical Impedance Analysis is generally preferred and used herein as it conveys the most information in its terms. Other generally equivalent terms which may be used include Bioimpedance Analysis or Biological Impedance Analysis, Biological Impedance Interface, Electrical Bio-impedance, Electrical Impedance Analysis, and similar terms and combination of terms.

2. Relevant State of the Art and Description of Related Prior Art

As has been noted above, the present invention relates to BIA in general and especially to measurements as may be required on cattle and their carcasses.

Cattle are important animals having significant economic, and agricultural significance. Various measurements may be made or desired relating to their development, use, and breeding. Similar concerns and measurements may be made on other animals.

Among the measurements of particular interest are those known as bioelectrical impedance analysis, although as has been noted the present invention is not limited to such specific measurements or techniques.

Bioelectrical Impedance Analysis may be used to measure and analyze a wide range of ionic and charge transfer processes in bio-materials and biological systems in general.

As a matter of general background to the present invention, it may be helpful to note the following terms:

Electricity is the movement of electrons.

Electrons have a negative charge. Free electrons will flow or move towards a positive charge or down an electrical gradient towards a less negative charge.

Amperes (Amps) is the number of free electrons flowing or moving per unit time. Sometimes this flow of electrons is referred to as “Intensity” or “I”. Sometimes this flow is referred to as “electrical current”. In many situations, it may be best to think about amperes as the amount of or volume of electrons that are moving per unit of time. One ampere=6.25×10¹⁸ electrons per second.

Conductors: The flow of electrons moves along a material or substance called a “conductor”. Some substances offer more or less resistance to the flow of electrons than others. Those that offer little resistance to the flow of electrons are considered “good conductors” A good conductor is a material that has electrons that are less tightly bound and therefore, more free to move. In a bad conductor, the electrons are more tightly bound and less free to move. A really bad conductor is called an “insulator”.

Volts represent the potential difference in charges between two points in or along a conductor. That means that there is an electrical gradient between the two points. In other words, there are more negative charges (electrons) at one point than at the other. The more positively charged point would exert an attractive force or pull on the electrons toward it. The attractive force is called an “electromotive force”.

The relationship between amperes, volts and resistance to flow of electrons may be expressed by Ohm's law: Volts=Amperes×Resistance in Ohms. All conductors offer some resistance to the flow of electrons.

A “capacitor in an electric circuit is a non-conductor (insulator, sometimes called a “dielectric”) that is sandwiched between two conductors. As the electrons flow down the conductor, it comes to the capacitor. Because the capacitor is a non-conductor, the electrons begin to pile-up on one side of it. As more negatively charged electrons accumulate, the potential electrical difference between the negative side of the capacitor and the relatively positively charged side increases. Like charges repel each other. So, as the negatively charged electrons accumulate on one side of the capacitor, the increasing negative charge on that side of the capacitor repels the negatively charged electrons on the other side of the capacitor. That results in one side of the capacitor with more electrons next to the capacitor than the other side. When the potential difference in negative electrons between the two sides is sufficiently great, the electrons on the relatively less negative side of the capacitor begin to move away from the capacitor and down the conductor. We can view a capacitor as a non-conductor that results in an increase in voltage.

Sometimes, capacitance is thought of as the amount of electrons necessary to raise the potential by a specific amount. At other times, capacitance may be thought of as the amount of electrons that can be “stored” on a surface (i.e., the negative side of the capacitor), before the electrical current moves on. Capacitance is measured in “Farads”.

A biological cell membrane is composed of a biomolecular layer of phospholipids. Lipids are poor electrical conductors. They are so poor as to be viewed as non-conductors. When an electrical current flows through the fluids in the body (a relatively good conductor) and comes to a cell membrane such as a red blood cell, the cell membrane acts as a capacitor, the capacitance of which can be measured.

Bioelectrical Impedance Analysis (BIA) measures the impedance or opposition to the flow of electrical current through body fluids. Impedance is low in lean tissue where intracellular fluid and electrolytes are primarily contained, but high in fat tissue. Impedance is generally proportional to body water volume. In practice, a small constant current, typically 800 uA at a fixed frequency, for example 50 kHz, is passed between electrodes spanning the body parts in question and the voltage drop between electrodes provides a measure of impedance.

The impedance of a biological tissue comprises two components, the resistance and the reactance. The conductive characteristics of body fluids provide the resistive component, whereas the cell membranes, acting as imperfect capacitors, contribute a frequency-dependent reactive component.

Impedance measurements made over a range of low to high (1 MHz) frequencies, allow the development of predictive equations. For example, equations may relate impedance measures at low frequencies to extracellular fluid volumes and at high frequencies to total body fluid volume. This approach is known a multi-frequency bioelectrical impedance analysis (MFBIA).

The BIA measurements in general involve the measurement of:
a.) resistance in ohms {“R”}
b.) reactance in ohms {“Xc”} [basically defined as the opposition to transmission of electrical energy through a capacitor.]
c.) impedance in ohms {“Z”} [basically defined as Z=√[R²+(Xc)²] (i.e. the square root of [R squared+Xc squared]).

The above paraphrased from tutorial papers of Dr. Neal Latman and from pp. 29-32 Horowitz & Hill, The Art of Electronics (2d Ed.) Cambridge University Press, Cambridge, Mass., 1989.

Further background for the present invention is set forth in Marchello, M. J. and W. D. Slanger; “Bioelectrical Impedance Can Preselect Skeletal Muscle and Fat-Free Skeletal Muscle of Beef Cows and Their Carcasses;” J. Am. Sci. 1994,721:3118-3123.

See also, Marchello, M. J., J. E. McLennan; D. V. Dhuyvetter; and W. D. Slanger; “Determination of Saleable Product in Finished Cattle and Beef Carcasses Utilizing Bioelectrical Impedance Technology;” J.Anim. Sci; 1999.77:2965-2970.

Further background of the present invention is provided by Forro, Mariam, Scott Cieslar, Gayle L. Ecker, Angela Walzak, Joy Hahn, and Michael I. Lindenger, “Total body water and ECFV measured using bioelectrical impedance analysis and indicator dilution in horses”: J. Appl Physiol 89: 663*671,2000. which to some extent appears to teach away from the present invention, see sections on the linear regression analysis.

Also see, Fielding, C. Langdon, Gary Magdesean, Denise A. Elliott, Larry D. Cowgell, and Gary P. Carlson; “Use of multifrequency bioelectrical impedance analysis for estimation of total body water and extracellular and intracellular fluid volumes in horses”, AJVR, Vol 65, U.S. Pat. No. 3,320,326 March 2004.

See also U.S. Pat. No. 6,850,798 which measures animal body fat via the hooves and foot pads; U.S. Pat. No. 6,308,096 and U.S. Pat. No. 6,321,112 at their FIG. 25 and 2001/0007055 which purports to measure fatigue see FIG. 12.

U.S. Pat. No. 6,360,124 is handheld and U.S. Pat. No. 6,400,983 which employs hand electrodes.

U.S. Pat. No. 6,477,409 measures metabolism and U.S. Pat. No. 6,487,445 utilizes calipers.

U.S. Pat. Nos. 6,490,481; 6,509,748; and 2003/0216665 employ multiple electrodes with other body data while U.S. Pat. Nos. 6,516,221 and 6,725,089 feature graphic displays.

U.S. Pat. No. 6,567,692 utilizes multiple sites, U.S. Pat. No. 6,621,013 selects body information to be evaluated.

2003/0176808 allows for multiple fat layers.

2004/0019292 permits use in identification.

2004/0171963 and 2005/0059902 focus on body composition and 2004/0236245 on muscle mass.

2005/0124909 is directed to the measurement of body fat in animals.

U.S. Pat. No. 6,978,170 focuses on electrode positioning.

2006/0094979 and 2006/0111645 utilize multiple pairs of electrode systems.

Other references of interest include: U.S. Pat. Nos. 3,602,215; 3,851,641; 3,871,359; 3,971,365; 4,008,712; 4,116,231; 4,336,873; 4,377,170; 4,423,792; 4,144,763; 4,557,271; 4,557,271; 4,493,362; 4,578,635; 4,557,271; 4,773,492; 4,831,242; 4,831,527; 4,844,187; 4,947,862; 4,805,621; 4,895,163; 4,911,175; 4,919,145; 4,947,862; 5,063,937; 5,086,781; 5,203,344; 5,579,782; 6,088,615; 6,208,890; 5,722,396; 5,819,741; 6,004,312; 6,188,925; 6,280,396; 6,308,096; 6,354,996; 6,370,425; 6,393,317; 6,400,983; 4,949,727; 5,052,405; 5,105,825; 5,372,141; 5,458,117; 5,720,296; 5,746,214; 5,817,031; 5,840,042; 6,151,523; 6,198,964; 6,256,532; 6,265,882; 5,483,970; 5,335,667; 5,415,176; 5,435,3115; 5,449,000; 5,595,189; 5,611,351; 5,615,689; 5,749,369; 5,335,667; 5,817,031; 6,088,615; 6,292,690; 2002/0026173; 6,370,425; 6,393,317; 2002/0151815; 6,473,643'2002/0151311; 6,631,292; 2004/0002662; 5,088,489; 5,335,667; 5,718,850; 5,720,296; 5,729,905; 6,038,465; 6,088,615; 6,321,112; 6,398,740; 6,440,068; 6,327,495; 5,371,469; 5,483,970; 5,503,157; 5,865,763; 6,011,992; 6,339,722; 6,442,422; 6,450,955; 6,490,481; 6,487,445; 6,516,221; 6,526,315; 6,567,692; 5,579,782; 5,819,741; 6,004,312; 6,168,563; 6,280,396; 6,308,096; 6,685,654; 2004/0077968; 6,752,760; 2004/0260196; 6,865,415; 2005/0059903/; 2005/0080352; 6,889,076; 2005/0101875; 2005/0171451; 2005/0177060; 2005/0177062; 2005/0192488; 2005/0209528; 2006/0025701; 2006/0094978.

While a number of Biological Impedance Analysis (BIA) systems are shown and taught by the above art, they, in general, fail to recognize the importance of the electrode system and its critical significance along with the selection of the critical parameters to be employed in such evaluations.

### BRIEF SUMMARY OF THE INVENTION

The present invention relates to the measurement and analysis of the state of hydration as applied in connection with the measurement of the percentage of fat trim and of saleable meat for use in connection with beef, cattle, and their carcasses.

The present invention may be used for information relative to salability, treatment of disease and illness and in the selection of breeding stock.

The present invention while designed primarily for use with cattle and their carcasses can be used with other animals including but not limited to, sheep, goats, hogs and dogs.

The present invention can be utilized to measure, or to be a part of a system to measure or evaluate such parameters as total body water, extra and intra-cellular fluid, plasma, lean muscle mass, fat, the extent of marbling, percentage of saleable retail cuts, fat trim yield, percentage fat trim, yield grade, quality grade, percentage saleable meat yield, phase angles, and general, overall health.

### Objects

Pursuant to the foregoing, it may be regarded as an object of the present invention to overcome the deficiencies of and provide for improvements in the state of the prior art as described above and as may be inherent in the same or as may be known to those skilled in the art.

It is a further object of the present invention to provide a process and any necessary apparatus for carrying out the same and of the forgoing character and in accordance with the above objects which may be readily carried out with and within the process and with comparatively simple equipment and with relatively simple engineering requirements.

Still further objects may be recognized and become apparent upon consideration of the following specification, taken as a whole, in conjunction with the appended drawings and claims, wherein by way of illustration and example, an embodiment of the present invention is disclosed.

As used herein, any reference to an object of the present invention should be understood to refer to solutions and advantages of the present invention which flow from its conception and reduction to practice and not to any a priori or prior art conception

The above and other objects of the present invention are realized and the limitations of the prior art are overcome by providing a new and improved method and process applicable to measurements to be made on animals such as cattle and their carcasses.

### Technical Problems to be Solved

The need for a system to provide accurate, reliable and repeatable measurements has long existed and been an unfulfilled need prior to the invention of the present apparatus and process.

In particular, the uneven topographic surfaces presented by certain animals such as cattle and the like over uneven muscles and bone structures have long presented a problem of obtaining accurate and reproducible measurements in various electrical systems including those directed to bioelectrical impedance analysis.

Prior attempts have failed to find specific points for measurement that provide easily definable landmarks for fast, accurate, and reproducible results. Prior attempts have failed to find the critical, significant variables needed to accurately predict percent saleable meat yield and percent fat trim. Prior attempts have failed to create a formulation of variables to easily, quickly, and accurately predict percent saleable meat and percent fat trim using BIA.

### BRIEF DESCRIPTION OF THE DRAWINGS AND THEIR SEVERAL VIEWS

The above mentioned and other objects and advantages of the present invention and a better understanding of the principles and details of the present invention will be evident from the description taken in conjunction with the appended drawings.

The drawings constitute a part of this specification and include exemplary embodiments of the present invention, which may be embodied in various forms. It is to be understood that in some instances various aspects of the invention may be shown as exaggerated, reduced, or enlarged or otherwise distorted to facilitate an understanding of the present invention.

In the drawings appended hereto:

FIG. 1 is a schematic flow sheet showing the system of the present invention. It is diagrammatic, illustrative, and not in proportion.

In the accompanying drawings, like elements are given the same or analogous references when convenient or helpful for clarity. The same or analogous reference to these elements will be made in the body of the specification, but other names and terminology may also be employed to further explain the present invention.

### GENERAL DESCRIPTION OF THE INVENTION, DETAILED DESCRIPTION OF PREFERRED EMBODIMENTS OF AND BEST MODE FOR CARRYING OUT THE PRESENT INVENTION

The present invention relates to methods and apparatus for use on animals in Bioelectrical Impedance Analysis (BIA) and other electrical measurements. The electrical measurements may be directed to any of a number of areas of electrical activities either of endogenous or exogenous origin. The preferred electrodes are for use on cattle and/or their carcasses, but may be used in connection with a wide variety of animals. The electrodes systems are intended to overcome problems in the prior art as noted above. They will provide a defined distance between the contact points of the electrodes. The electrodes and their holders are designed to provide to provide accurate and reproducible measurements.

The present invention may be used and/or adapted for use in any Bioelectrical Impedance System.

The electrodes may have attachment clips of various known designs.

The system is not limited to hard wired transmission of its power voltage or signals.

The electrode holder includes a deck which has a handle. A protective partition which may have an opening guards the upper portion of the electrode attachment which may be adapted to receive a hypodermic needle or other needle, probe, solid wire, and/or syringe (not shown). The length and gage of the wire, needle or the like is as appropriate to the specific animal, carcass or use as are the specific materials of construction of the needle, wire or probe. The lower end of attachment is adapted to secure a hypodermic needle (not shown). The lower end of attachment is protected by a shield which prevents rocking of the needle and assists in controlling the depth of penetration. Holes allow for the attachment of clips and leads.

For a further understanding of the nature, function, and objects of the present invention, reference should now be made to the following detailed description taken in conjunction with the accompanying drawings. Detailed descriptions of the preferred embodiments are provided herein, as well as, the best mode of carrying out and employing the present invention. It is to be understood, however, that the present invention may be embodied in various forms. Therefore, specific details disclosed herein are not to be interpreted as limiting, but rather as a basis for the claims and as a representative basis for teaching one skilled in the art to employ the present invention in virtually any appropriately detailed system, structure, or manner. The practice of the present invention is illustrated by the following examples, which are deemed illustrative of both the process taught by the present invention and of the results yielded in accordance with the present invention.

Turning now to matters of function and operation in addition to structure, the electrode holder may have a hypodermic needle with or without caps and may be of the screw on, snap-on or quick release type.

The handle on the top of the electrode holder makes it easier to hold on and control the electrode holder.

The cattle or bovine carcass embodiment of the present invention may be used to measure the amount of lean meat and/or the amount of fat. The present invention, to be more specific, can be utilized to measure, or to be a part of a system to measure or evaluate such parameters as total body water, extra and intra-cellular fluid, plasma, lean muscle mass, fat, the extent of marbling, percentage of saleable retail cuts, fat trim yield, percentage fat trim, yield grade, quality grade, percentage saleable meat yield, phase angles, and general, overall health.

Any type of needle, probe, wire or the like can be attached to the electrode holder.

A needle electrode holder may be used to permit and/or perform tests on live animals or carcasses. In particular, the present invention may be used in disease prediction, preventative analysis, and in the detection of contamination.

Well known fast needle exchange systems such as the “Luer lock” or other similar systems may be used to attach the needle electrodes to the bulkhead. See U.S. Pat. No. 5,637,101 and RE 038964.

A tetra-polar system may be employed in connection with the present invention.

The electrode/needle holder provides for the attachment of alligator clips or similar electrode attachment clips. These bovine electrodes or penetrating electrodes or probes can be called “BIA Bovine Penetrating Electrodes.”

The holder has a platform structure on the bottom to control the depth of penetration as well as to control or limit rocking motion of the holder and of the electrodes.

The holder and its electrodes may be sterilized in a bath with a temperature higher than 180° F. or otherwise in accordance with the current industry standards.

The Plexiglas structure of the electrode holder along with providing for good visibility of and within the holder also provides for cleaning and the detection of any problems with the cleaning. Single or multiple units containing sterile cleaning fluid may be used to clean the electrode holder in accordance with current industry standards.

In operation, the measurements may be made in less than 30 seconds on live animals and less than 7 seconds on carcasses with no application of cream or gel to the carcasses.

The present invention may be used:
(1) in feedlot operations,
(2) to determine or predict the grades of meat likely to be produced such as “prime”, “choice” and the like,
(3) as a part of the overall determination of body composition,
(4) to predict disease,
(5) in preventative analysis,
(6) in the detection of contamination,
(7) in slaughterhouse or abattoir operations, and
(8) in meat processing operations.

The present invention may be used to predict certain illnesses by the proper application of phase angle shifts as well as direct impedance measurements.

The present invention may utilize retractable or “spring shot” needles which will allow for the administration of vaccinations and antibiotics and the like through the electrode needles. The present invention is intended to use and hold penetrating electrodes and may in addition to or as a separate device may utilize additional and/or separate injection devices.

For further details of the electrodes and the electrode holders for such electrodes, see the co-pending patent application designated CCC 0806 B, entitled ELECTRODE HOLDER FOR USE ON CATTLE AND THE LIKE AND ON THEIR CARCASSES, filed contemporaneously herewith, which is hereby incorporated by reference with the intention that it be treated and understood as fully as if set forth herein in its entirety.

The placement of the electrodes is of importance in achieving reproducible and accurate results. That is, it is important that the path over which the impedance measurements are made is representative of and comparable with properties associated with the saleable meat. Some of the prior art attempts have placed the electrodes on the outside of the beef carcass which may result in a high exposure to fat as compared to the exposure to meat which may skew the results. Further, in the uncooled carcass (which represents the normal and usual operating conditions under which such measurements are or will be made commercially) the consistency of the fat may interfere with a consistent, solid electrical contact between the electrodes and the beef carcass.

The preferred placement of electrodes in connection with the present invention is as follows:

The beef carcass is usually split roughly along the midsagittal plane to divide the body into right and left sides. As noted herein either side may be used for the measurements of the present invention and the side actually used has been noted in the examples referred to herein.

The sides are usually hung or suspended in the meat processing plant from the caudal or posterior end of the carcass with the anterior (cranial) or head end hanging downward. These reference positions are noted for the purpose of relative positioning realizing, of course, that this orientation is not necessary for effective BIA measurements to be made in accordance with the present invention.

The preferred placement of the electrodes in the present invention is on the inside wall of the beef carcass.

One set of electrodes is inserted in the semimembranosus muscle posterior to the aitchbone. The aitchbone is the buttock, hipbone, or rump bone of beef cattle.

The second set of electrodes was inserted in the intercostal muscle adjacent to the first (1^{st}) and third (3^{rd}) ribs. The intercostal muscles are the muscles that run between the ribs and help to form and move the chest wall.

The two pairs or sets of electrodes are aligned parallel to the length of the beef carcass.

The source or signaling electrode of each pair is positioned to the outside ends (i.e., the anterior and the caudal ends, respectively) of the beef carcass.

A multiple linear regression analysis was performed to provide the following relationship between % Fat or Trim and six (6) independent variables each at the 95.0% confidence level.

$$\% Fat ( Trim ) = Constant {C}_{1} + {P}_{1} Sex Factor + {P}_{2} Resistance + {P}_{3} Reactive Density + {P}_{4} Left Side Weight + {P}_{5} Electrode Gap + {P}_{6} Electrical Volume .$$

A particularly preferred embodiment is:

$$\% Fat ( Trim ) = - 0.05 + 0.04 Sex Factor - 0.002 Resistance - 0.001 Reactive Density + 0.004 Left Side Weight + 0.007 Electrode Gap - 0.010 Electrical Volume .$$

A more general preferred formulation is:

$$\% Fat ( Trim ) = [ 0.24 to - 0.34 ] + [ 0.07 to 0.017 ] Sex Factor + [ 0.0007 to - 0.005 ] Resistance - [ 0.0002 to 0.003 ] Reactive Density + [ 0.005 to 0.003 ] Left Side Weight + [ 0.015 to - 0.0003 ] Electrode Gap - [ 0.004 to 0.015 ] Electrical Volume .$$

A multiple linear regression analysis was performed to provide the following relationship between % Saleable Yield and six (6) independent variables at the 95.0% confidence level.

$$\% Saleable Yield = Constant {C}_{2} + {P}_{7} Sex Factor + {P}_{8} Left Side Weight + {P}_{9} Electrode Gap + {P}_{10} Electrical Volume + {P}_{11} Resistive Density + {P}_{12} Reactive Density .$$

A particularly preferred embodiment is:

$$\% Saleable Yield = 0.99 - 0.017 Sex Factor - 0.011 Left Side Weight - 0.003 Electrode Gap + 0.013 Electrical Volume + 0.002 Resistive Density + 0.002 Reactive Density .$$

A more general preferred formulation is:

$$\% Saleable Yield = [ 1.25 to 0.73 ] + [ 0.007 to - 0.04 ] Sex Factor - [ 0.0009 to 0.02 ] Left Side Weight - [ 0.0008 to 0.006 ] Electrode Gap + [ 0.02 to 0.003 ] Electrical Volume + [ 0.005 to - 0.0007 ] Resistive Density + [ 0.002 to 0.001 ] Reactive Density .$$

The above formulations are obtained by a constant; a value for Sex Status, where 1=Male and 2=Female; the reactance in ohms; the impedance in ohms, and the electric volume, where the electric volume (EV) is the electrode gap [EG] squared divided by the resistance [R].

EV=[EG]²/R

The electrode gap is in inches and the resistance in ohms. The electrode gap is the distance between electrodes in inches.

The left side weight is specified herein, but the right side weight could be used or both side weights divided by two (2) may be used.

The Electrical Density of the cattle or carcass is a concept employed herein. It is composed of two (2) components: a Reactive Density and a Resistive Density.

If the weight of the left side of the carcass is designated WT and the distance between electrodes is called the Electrode Gap, EG, while the resistance in ohms is [R] and the reactance in ohms is [Xc], the Reactive Density and Resistive Density may be defined as follows:

Reactive Density=[WT]²/{[EG]²/Xc}, and

Resistive Density=[WT]²/{[EG]²/R}.

As has been previously discussed above, bioelectrical impedance analysis (BIA) is based on the measurement of the impedance or opposition to the flow of electrons or an electrical current through the body fluids which are contained primarily in the lean and fat tissue of the body. In general, impedance is low in the lean tissue, where intracellular fluids and electrolytes are primarily contained, but high in fat tissue. Impedance is thus, in general, proportional to body water volume (TBW or total body water).

In making a bioelectrical impedance analysis, a small constant current, typically 800 μA, at a fixed frequency, such as 50 kHz, is passed between electrodes spanning the body and the voltage drop between the electrodes is taken as a measure of the impedance.

The impedance of a biological tissue may be viewed as comprising two (2) components: the resistance and the reactance. The conductive characteristics of the body fluids provide the resistive component and the cell membranes, acting as imperfect capacitors, contribute a frequency-dependent reactive component.

Impedance measurements may be made at a fixed frequency or over a range of low to high frequencies (on the order of 1 MHz) allowing the development of predictive equations relating the impedance measures at low frequencies to point to extracellular fluid volume and at high frequencies to total body fluid volume. Such an analysis is known as multi-frequency bioelectrical impedance analysis (MFBIA).

The electrodes employed as well as their holders may be important factors affecting accuracy and reproducibility. See for example the co-pending application if the present inventors filed concurrently herewith directed to the preferred electrode holders.

The phase angle is the difference between the phase of a sinusoidally varying quantity and the phase of a second quantity which varies sinusoidally at the same frequency. In BIA the difference in phase between the components affected by the capacitive elements (in the reactive component) and those without a capacitive effect (in the resistive component).

The examples set forth above used a single frequency of 50 kHz. Of course, multiple frequencies can be used as a part of the present invention.

In accordance with the teachings of the present invention the signal received from the electrode(s) can be processed in conjunction with data entered into the unit according to one or more of the above formulations of factors to produce the desired output information.

The analyzing monitor unit will transmit a signal to one or more electrodes which will cause a flow of electrons to pass through the tissues of an animal so that the impedance of those tissues can be measured and transmitted to the electronic circuits of the analyzing monitoring unit where that information together with the entered data can be used to produce the desired measured quantities.

The electrical/electronic circuits may be hardwired circuits containing known digital or analog elements or both. The analyzing monitoring unit of the present invention can also employ appropriate software to the same ends in a general purpose digital computer, a special purpose analog computer or in a hybrid unit containing digital and analog elements.

The analyzing monitoring unit of the present invention may take the form of a printed circuit or integrated circuit, microcircuit, microchip, silicon chip or an item known simply as a chip. Any and all of the above may be analog, digital, or mixed, hybrid signal devices, where a hybrid or mixed signal device has both analog and digital elements on the same chip and/or within the same circuits.

Illustrative of such circuit devices are U.S. Pat. Nos. 3,029,366; 3,138,743; 3,138,747; 3,261,081, and 3,434,015. The electronic elements and circuits for carrying out the present invention are all well known to those skilled in the arts.

The electrode(s) and electrode holder for use within the present invention are disclosed in a concurrently filed application by the present inventors and is commonly co-owned.

The electronic components and circuits as set forth herein can, within the scope of the present invention be replaced in whole or part by alternative means including but not limited to mechanical, pneumatic means, optical chips, molecular, holographic and quantum elements and/or computers.

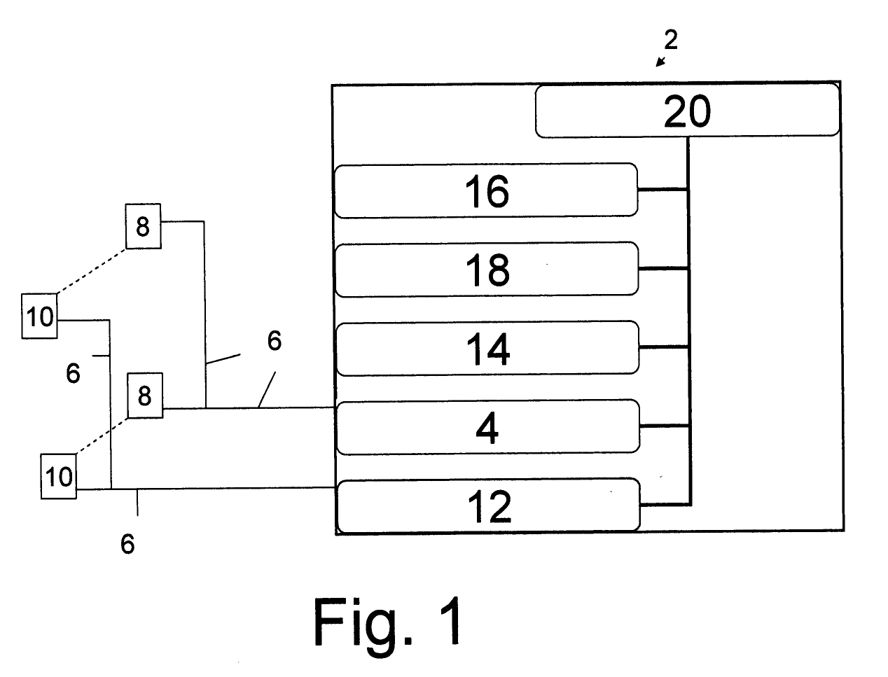

In operation, the monitor 2 of the present invention, as is shown in FIG. 1, powered by power source 20 transmits a signal as described herein from it by transmitting circuits 4 via wires 6 (or by wireless means) to an electrode 8 (or electrodes) mounted within an electrode holder (not shown in detail but disclosed in a co-pending application of the present inventors which is co-owned and filed concurrently herewith). The signal creates a potential difference between the electrodes which creates a current flow between the electrodes reflecting the impedance encountered. A signal reflecting that impedance is transmitted from electrode 10 to the receiving circuits 12. The resulting signal is passed to the memory, logic, processing and adding circuits of the processing unit 14. External inputs (such as the sex, side weight, electrode gap and the like) may be submitted by input means 16. This input data has been or is entered into the processing unit 14 where it is processed so that the desired information may be displayed by and at the output display 18.

In the preferred embodiment as described above a tetrapolar arrangement of electrodes is preferred in which there are two pairs of electrodes, one pair at each position. Each pair has a sending and a receiving electrode within this system.

The placement of the electrodes as disclosed herein is important to the results and the functioning of the system as well as to the equations as disclosed herein.

### Alternative and Alternative Embodiments

While throughout this description, we have referred to various materials, chemicals, and apparatus as being presently preferred, it will be clear to one skilled in the art that other materials, chemicals, apparatus, methods, processes, steps and embodiments may be employed which will also provide the advantages as herein set forth in connection with the present invention. The present invention is not limited to the representative examples disclosed herein. Moreover, the scope of the present invention covers conventionally known variations and modifications to the system and the components described herein, as would be known by those skilled in the art. Such variations and equivalents are intended to be within the scope of the present invention. Accordingly, the invention is to be broadly construed and is to be limited only by the scope and spirit of the claims appended hereto.

To provide a description of the present invention that is both concise and clear, various examples of ranges have been set forth herein and in all cases should be read as though expressly identified with the phrase “including all intermediate ranges and combinations thereof”. Examples of specific values (e.g., ohms, ° C., μm, kg/L, volts, amps, current, intensity, etc.) that can be within a cited range by the reference to “including all intermediate ranges and combinations thereof” include 0.000001, 0.00001, 0.0001, 0.001, 0.002, 0.003, 0.004, 0.005, 0.006, 0.007, 0.008, 0.009, 0.01, 0.02, 0.03, 0.04, 0.05, 0.06, 0.07, 0.08, 0.09, 0.10, 0.15, 0.20, 0.25, 0.30, 0.35, 0.40, 0.45, 0.50, 0.55, 0.60, 0.65, 0.70, 0.75, 0.80, 0.85, 0.90, 0.95, 1.0, 1.1, 1.2, 1.30, 1.31, 1.32, 1.33, 1.34, 1.35, 1.36, 1.37, 1.38, 1.39, 1.40, 1.41, 1.42, 1.43, 1.44, 1.45, 1.46, 1.47, 1.48, 1.49, 1.50, 1.51, 1.52, 1.53, 1.54, 1.55, 1.56, 1.57, 1.58, 1.59, 1.60, 1.61, 1.62, 1.63, 1.64, 1.65, 1.66, 1.67, 1.68, 1.69, 1.70, 1.8, 1.9, 2.0, 2.1, 2.2, 2.3, 2.4, 2.5, 2.6, 2.7, 2.8, 2.9, 3.0, 3.1, 3.2, 3.3, 3.4, 3.5, 3.6, 3.7, 3.8, 3.9, 4.0, 4.1, 4.2, 4.3, 4.4, 4.5, 4.6, 4.7, 4.8, 4.9, 5.0, 5.1, 5.2, 5.3, 5.4, 5.5, 5.6, 5.7, 5.8, 5.9, 6.0, 6.1, 6.2, 6.3, 6.4, 6.5, 6.6, 6.7, 6.8, 6.9, 7.0, 7.1, 7.2, 7.3, 7.4, 7.5, 7.6, 7.7, 7.8, 7.9, 8.0, 8.1, 8.2, 8.3, 8.4, 8.5, 8.6, 8.7, 8.8, 8.9, 9.0, 9.1, 9.2, 9.3, 9.4, 9.5, 9.6, 9.7, 9.8, 9.9, 10.0, 11, 12, 13, 14, 15, 16, 17, 18, 19, 20, 21, 22, 23, 24, 25, 26, 27, 28, 29, 30, 31, 32, 33, 34, 35, 36, 37, 38, 39, 40, 41, 42, 43, 44, 45, 46, 47, 48, 49, 50, 51, 52, 53, 54, 55, 56, 57, 58, 59, 60, 61, 62, 63, 64, 65, 66, 67, 68, 69, 70, 71, 72, 73, 74, 75, 76, 77, 78, 79, 80, 81, 82, 83, 84, 85, 86, 87, 88, 89, 90, 91, 92, 93, 94, 95, 96, 97, 98, 99, 100, 101, 102, 103, 104, 105, 106, 107, 108, 109, 110, 111, 112, 113, 114, 115, 116, 117, 118, 119, 120, 121, 122, 123, 124, 125, 126, 127, 128, 129, 130, 131, 132, 133, 134, 135, 136, 137, 138, 139, 140, 141, 142, 143, 144, 145, 146, 147, 148, 149, 150, 151, 152, 153, 154, 155, 156, 157, 158, 159, 160, 161, 162, 163, 164, 165, 166, 167, 168, 169, 170, 171, 172, 173, 174, 175, 176, 177, 178, 179, 180, 181, 182, 183, 184, 185, 186, 187, 188, 189, 190, 191, 192, 193, 194, 195, 196, 197, 198, 199, 200, 201, 202, 203, 204, 205, 206, 207, 208, 209, 210, 211, 212, 213, 214, 215, 216, 217, 218, 219, 220, 221, 222, 223, 224, 225, 226, 227, 228, 229, 230, 231, 232, 233, 234, 235, 236, 237, 238, 239, 240, 241, 242, 243, 244, 245, 246, 247, 248, 249, 250, 275, 300, 325, 350, 375, 400, 425, 450, 475, 500, 525, 550, 575, 600, 625, 650, 675, 700, 725, 750, 775, 800, 825, 850, 875, 900, 925, 950, 975, 1000, 1050, 1100, 1150, 1200, 1250, 1300, 1350, 1400, 1450, 1500, 1600, 1700, 1800, 1900, 2000, 3000, 4000, 5000, 6000, 7000, 8000, 9000, 10,000, or more and so forth.

The above conventions may be understood by means of a number line a common element of elementary mathematics. It can be constructed by marking off two points: zero (the origin) and one (1). The distance from 0 to the point 1 is called the unit segment. The distance between all consecutive whole numbers is the same. When measurements fall somewhere between whole numbers. we may describe the situation in terms of a fractional length or in decimal terms of tenths, hundredths, thousandths and so forth. For example, if a measurement falls between 4 and 5, we may find that it is closer to 4.3 than 4.4. If we want more precision (and it is appropriate), we may continue to “zoom in” in which case we move more decimal places to the right. For numbers less than 5 in the relevant place one may round down and for numbers greater than 5 one may round up. When the relevant place contains a 5, the rule is to round so that the last nonzero digit is an even number. Whenever a range is given herein, the above rules are intended to apply and the range is intended to cover all points on the number line from the lowest number to be rounded to the bottom of the range to the highest number to be rounded to the top of the range.

General ranges and the usual definitions for significant figures for each type of unit (e.g., ohms, %, ° C., μm, kg/L), are contemplated. Examples of values that can be within a cited percentage range, as applicable, include 0.001% to 100%, including all intermediate ranges and combinations thereof. Examples of values that can be within a thickness range (e.g., coating and/or film thickness upon a surface), as applicable, in micrometers (“μm”), that can be within a cited range include of 1 μm to 2000 μm, including all intermediate ranges and combinations thereof. Similar examples may be understood to apply to all of the units and systems of units mentioned above, such as ohms and the like or otherwise discussed below.

The following comments are intended to apply to all units and their conversions to whatever system of units including but not limited to length (m), mass (kg), time (s), speed (m/s), including but not limited to angular frequency or velocity (radian/second), resistance (ohm), reactance (ohms), impedance (ohms) capacitance (farads), charge (coulomb), current (ampere), electromotive force (volt), work or energy (oule), force (Newton), frequency (Hertz), inductance (Henry), magnetic field (B, Tesla), magnetic flux (Weber), potential (volt) power (watt), etc.

Specific units from one or more of the following systems may be used including but not limited to S.I., m.k.s. practical units; Gaussian units; Heaviside-Lorentz units; electrostatic units, and/or electromagnetic units.

In addition to the standard units the micron (μ=10⁻⁶ m) and Angstrom (Å=10⁻¹⁰ m) are frequently used and may be used herein.

### SUMMARY

The present invention includes a method and apparatus for measuring and analyzing the state of hydration of cattle or their carcass including providing power to a transmitting circuit to transmit a signal to electrodes resulting in a potential difference across the electrodes causing a flow of current between the electrodes reflecting the impedance encountered and sending a signal reflecting such information to receiving circuits which pass that data to processing circuits which process that data with other external inputs to produce an output display reflecting an indication of the state of hydration of the animal, comprising:

means for providing a voltage difference across two or more penetrating electrodes; means for maintaining said electrodes in a fixed spatial relation and in good electrical contact with the tissues to be measured; means for measuring the impedance of said animal or carcass in the region of or between the electrodes; means for transmitting the measured data to processing circuits which process that data with other external inputs to produce an output display reflecting an indication of the state of hydration of the animal, wherein the other external inputs include one or more of the factors for sex, left side weight, and electrode gap; and the output display provides indications of one or more of the outputs produced by formulations of the data reflecting the percentage of fat trim and the percentage of saleable yield and the analyzing monitoring unit may be selected from the group of embodiments consisting of software in a computer, hard wired circuits, printed circuits, integrated circuits, microcircuits, microchips, silicon chips, digital chips, analog chips, hybrid chips and combinations of any or all of the members of this group.

The present invention may employ an electrode holder comprising a pair of penetrating electrodes and a structure which controls the position of the electrodes with respect to each other.

It is noted that the embodiment described herein in detail for exemplary purposes is, of course, subject to many different variations in structure, design, application, and methodology. Because many varying and different embodiments may be made within the scope of the inventive concepts herein taught, and because many modifications may be made in the embodiment herein detailed in accordance with the descriptive requirement of the law, it is to be understood that the details herein are to be interpreted as illustrative and not in a limiting sense. It will be understood in view of the instant disclosure, that numerous variations of the invention are now enabled to those skilled in the art. Many of the variations reside within the scope of the present teachings. It is not intended to limit the scope of the invention to the particular forms set forth, but on the contrary, it is intended to cover such alternatives, modifications, and equivalents as may be included within the spirit and scope of the teachings and claims of the present invention. Accordingly, the invention is to be broadly construed and is to be limited only by the spirit and scope of the claims appended hereto.

What is claimed is:

1. A method for determining the percentage fat trim and the percentage of saleable yield by providing power to a transmitting circuit to transmit a signal to electrodes resulting in a potential difference across the electrodes causing a flow of current between the electrodes reflecting the impedance encountered and sending a signal reflecting such information to receiving circuits which pass that data to processing circuits which process that data with other external inputs to produce an output display reflecting an indication of the state of hydration of the animal and the percentage of fat trim and the percentage of saleable yield of the carcass, comprising
(a) providing a voltage difference across two or more penetrating electrodes;
(b) maintaining said electrodes in a fixed spatial relation and in good electrical contact with the tissue of the animal or its carcass;
(c) measuring the impedance of said in the region of or between the electrodes;
(d) transmitting the measured data to processing circuits which process that data with other external inputs to produce an output display reflecting an indication of the state of hydration of the animal including the percentage fat trim and the percentage saleable yield of the carcass, wherein the other external inputs include one or more of the factors for sex, left side weight, and electrode gap; and the output display provides indications of one or more of the outputs produced by formulations of the data reflecting the percentage of fat trim and the percentage of saleable yield and the analyzing monitoring unit may be selected from the group of embodiments consisting of software in a computer, hard wired circuits, printed circuits, integrated circuits, microcircuits, microchips, silicon chips, digital chips, analog chips, hybrid chips and combinations of any or all of the members of this group.

2. The method of claim 1 wherein the circuits employed are at least in part hard wired.

3. The method of claim 1 wherein the circuits employed are at least in part printed or integrated circuits.

4. The method of claim 1 wherein the circuits employed are at least in part contained on a chip.

5. The method of claim 1 wherein the percentage of fat trim is determined by the formulation:
$$[ 0.24 to - 0.34 ] + [ 0.07 to 0.017 ] Sex Factor + [ 0.0007 to - 0.005 ] Resistance - [ 0.0002 to 0.003 ] Reactive Density + [ 0.005 to 0.003 ] Left Side Weight + [ 0.015 to 0.0003 ] Electrode Gap - [ 0.004 to 0.015 ] Electrical Volume .$$

6. The method of claim 5 wherein the percentage of fat trim is determined by the formulation:
$$- 0.05 + 0.04 Sex Factor - 0.002 Resistance - 0.001 Reactive Density + 0.004 Left Side Weight + 0.007 Electrode Gap - 0.010 Electrical Volume .$$

7. The method of claim 1 wherein the percentage of saleable yield is determined by the formulation:
$$[ 1.25 to 0.73 ] + [ 0.007 to - 0.04 ] Sex Factor - [ 0.0009 to 0.02 ] Left Side Weight - [ 0.0008 to 0.006 ] Electrode Gap + [ 0.02 to 0.003 ] Electrical Volume + [ 0.005 to - 0.0007 ] Resistive Density + [ 0.002 to 0.001 ] Reactive Density .$$

8. The method of claim 7 wherein the percentage of saleable yield is determined by the formulation:
$$0.99 - 0.017 Sex Factor - 0.011 Left Side Weight - 0.003 Electrode Gap + 0.013 Electrical Volume + 0.002 Resistive Density + 0.002 Reactive Density .$$

9. An apparatus for determining the percentage of fat trim and/or saleable yield of cattle and their carcasses by providing power to a transmitting circuit to transmit a signal to electrodes resulting in a potential difference across the electrodes causing a flow of current between the electrodes reflecting the impedance encountered and sending a signal reflecting such information to receiving circuits which pass that data to processing circuits which process that data with other external inputs to produce an output display reflecting an indication of the state of hydration of the animal or its carcass, comprising:
means for providing a voltage difference across two or more penetrating electrodes; means for maintaining said electrodes in a fixed spatial relation and in good electrical contact with the tissues on which said measurements are to be made; means for measuring the impedance in the region of or between the electrodes; means for transmitting the measured data to processing circuits which process that data with other external inputs to produce an output display reflecting an indication of the percentage of fat trim and/or saleable yield, wherein the other external inputs include one or more of the factors for sex, electrode gap, and left side weight; and the output display provides indications of one or more of the outputs produced by formulations of the data reflecting the percentage of fat trim and or saleable yield; and the analyzing monitoring unit may be selected from the group of embodiments consisting of software in a computer, hard wired circuits, printed circuits, integrated circuits, microcircuits, microchips, silicon chips, digital chips, analog chips, hybrid chips and combinations of any or all of the members of this group.

10. The apparatus of claim 9 wherein the circuits employed are at least in part hard wired.

11. The apparatus of claim 9 wherein the circuits employed are at least in part printed or integrated circuits.

12. The apparatus of claim 9 wherein the circuits employed are at least in part contained on a chip.

13. The apparatus of claim 9 wherein the percentage of fat trim is determined by the formulation:
$$[ 0.24 to - 0.34 ] + [ 0.07 to 0.017 ] Sex Factor + [ 0.0007 to - 0.005 ] Resistance - [ 0.0002 to 0.003 ] Reactive Density + [ 0.005 to 0.003 ] Left Side Weight + [ 0.015 to - 0.0003 ] Electrode Gap - [ 0.004 to 0.015 ] Electrical Volume .$$

14. The apparatus of claim 13 wherein the percentage of fat trim is determined by the formulation:
$$- 0.05 + 0.04 Sex Factor - 0.002 Resistance - 0.001 Reactive Density + 0.004 Left Side Weight + 0.007 Electrode Gap - 0.010 Electrical Volume .$$

15. The apparatus of claim 9 wherein the percentage of saleable yield is determined by the formulation:
$$[ 1.25 to 0.73 ] + [ 0.007 to - 0.04 ] Sex Factor - [ 0.0009 to 0.02 ] Left Side Weight - [ 0.0008 to 0.006 ] Electrode Gap + [ 0.02 to 0.003 ] Electrical Volume + [ 0.005 to - 0.0007 ] Resistive Density + [ 0.002 to 0.001 ] Reactive Density .$$

16. The apparatus of claim 15 wherein the percentage of saleable yield is determined by the formulation:
$$0.99 - 0.017 Sex Factor - 0.011 Left Side Weight - 0.003 Electrode Gap + 0.013 Electrical Volume + 0.002 Resistive Density + 0.002 Reactive Density .$$
